(19) United States
(12) Patent Application Publication
(10) Pub. No.: US 2005/0201176 A1
(43) Pub. Date: Sep. 15, 2005

(54) Method for the preparation of nanometer scale particle arrays and the particle arrays prepared thereby

(75) Inventors: Giovanni Zangari, Tuscaloosa, AL (US); Ming Sun, Tuscaloosa, AL (US); Robert M. Metzger, Tuscaloosa, AL (US)

Correspondence Address: OBLON, SPIVAK, MCCLELLAND, MAIER & NEUSTADT, P.C., 1940 DUKE STREET, ALEXANDRIA, VA, 22314, US

(73) Assignee: UNIVERSITY OF ALABAMA, Tuscaloosa, AL (US)

(21) Appl. No.: 11/055,600

(22) Filed: Feb. 11, 2005

Related U.S. Application Data
(62) Division of application No. 09/827,900, filed on Apr. 9, 2001.

(51) Int. Cl. G11C 7/00

(52) U.S. Cl. 365/222

(57) ABSTRACT

A method is provided for the preparation of nanoscale particle arrays having highly uniform crystals of metal, semiconductor or insulator materials grown in nanopores in the surface of a substrate, wherein the method uses pulse-reverse electrodeposition of metals with a rectangular or square waveform in order to generate high homogeneity of crystals and high in-plane or out-of-plane anisotropy in a controlled manner, enabling the creation of a variety of devices, including but not limited to high density storage media.

### FIELD OF THE INVENTION

The present invention relates to a method for the production of nanometer scale particle arrays with high uniformity, the arrays thus prepared and their use in a variety of applications, including but not limited to, high density magnetic information storage media.

### DISCUSSION OF THE BACKGROUND

Conventional magnetic storage media are comprised of a continuous metallic layer deposited either on an aluminum alloy coated with a nickel-phosphorus layer, or on glass. In these media, each magnetic bit of information is stored in a region which contains a large number of crystalline grains, magnetized coherently in one of two preferred directions. Switching of the magnetization direction in such a granular medium is accompanied by noise, which gets proportionally worse with decreasing number of grains per bit. In order to achieve sufficient signal-to-noise ratio, the number of grains must be kept constant with varying recording density, and/or the uniformity of grain size and crystalline orientation must be increased. The conventional approach to increase the bit density is thus to decrease the crystal grain size together with the bit size, while keeping the number of grains per bit constant. This approach is reaching its physical limits, because further decrease of the bit size beyond those achieved in current recording systems (of the order of 50 Gb/in²) would require crystalline grains with size of few nanometers, which will spontaneously switch magnetization at normal operating temperature and will not be able to store information.

There is currently great technological and fundamental interest in the synthesis and properties of large area nanometer scale arrays of ferromagnetic particles. Such interest has been mainly triggered by the proposal (New et al; J. Vac. Sci. Technol. B 12, 3196 (1994); White et al; IEEE Trans. Magn. 33, 990 (1997); and Chou et al; J. Appl. Phys. 76, 6673 (1994)), that discrete magnetic recording schemes may overcome the thermal stability and noise limits of conventional hard disk media, as noted above. In the same context, these arrays would also be ideal model systems for the study of magnetic properties, interactions and thermal stability of ensembles of nanometer size particles. For both applications, long-range order of the array and extreme uniformity in size, structural and magnetic properties of the particles are essential. In addition, uniaxial anisotropy of the particles is important in providing definite magnetic states at remanence.

As an example of the above-noted discrete magnetic recording schemes, patterned media (White, U.S. Pat. No. 5,587,223), consisting of an ordered array of identical magnetic islands, are a possible means to overcome the thermal stability problem associated with increasing bit densities while reducing the grain size. In such media, the magnetic islands are configured such that only one bit of information is stored in each island. Several methods to produce such media—which would consist of large scale, nanometer size metal particle arrays—have been proposed, mostly based on lithographic processes such as electron beam (White et al,; IEEE Trans. Magn. 33, 990 (1997); Chou et al; J. Appl. Phys. 76, 6673 (1994)), nanometer-scale imprint (Chou, U.S. Pat. No. 5,772,905), and interferometric (Ross et al,; J. Vac. Sci. Technol. B 17, 3168 (1999)), lithography, followed by either blanket deposition and lift-off, or by selective electrodeposition, to define the shape and position of the magnetic islands. These methods all suffer of drawbacks that render them impractical for mass production.

On the contrary, self-assembly methods for template synthesis are advantageous, as they offer low-cost, high-throughput processes that naturally yield high quality short-range order. A general drawback of the latter however is the difficulty of achieving long range order over macroscopic distances, necessary both for tracking and write synchronization in patterned recording schemes (Hughes; IEEE Trans. Magn. 36, 521 (2000)), and for enabling meaningful studies of magnetic properties by use of magnetometry methods.

Anodization of aluminum Al is one process, that is capable of producing hexagonally ordered vertical nanopores (Masuda et al; Science 268, 1466 (1995)). Pore arrays with defect-free areas of up to about 100 μm² have been recently synthesized through a novel multi-step anodization process (Konovalov et al; in Electrochemical Technology Applications in Electronics, PV 99-34, The Electrochemical Society, NJ, p. 203). Furthermore, by use of a nano-stamping procedure (Masuda et al; Appl. Phys. Lett. 71, 2770 (1997)) or lithography to define micron-sized areas to be anodized (Li et al; Electrochem. Sol. St. Lett. 3, 131 (2000)), long range order of porous aluminum templates has been recently achieved.

The decoration of Al surfaces by electrodeposition of metals into anodized aluminum has been used commercially since at least 1923 (Bengough et al, Brit. Patent: 223,994 (1923)). Due to the rectifying nature of Al oxide films (barrier layer), magnetic metals and alloys can be electrodeposited into aluminum oxide pore structures by AC electrodeposition (Tsuya et al,. IEEE. Trans. Magn. 22, 1140 (1986)). These structures could be easily fabricated with high aspect ratio, and consequently they were first proposed as a template for the fabrication of perpendicular recording media (Koskenmaki, U.S. Pat. No. 4,472,248). The dimensions of the magnetic islands are determined by the pore size and their height is controlled by the deposition rate and duration (Li et al, IEEE Trans. Magn. 33, 3715 (1997)). Daimon et al, U.S. Pat. No. 5,480,694, teach the fabrication of magnetic arrays in alumite with in-plane magnetic anisotropy, but no discussion is present, nor are experimental results given, related to the uniformity in particle length.

Conventional AC electrochemical deposition employs sinusoidal voltage waveforms, which unfortunately yield a wide distribution of particle lengths and consequently poor uniformity of the magnetic properties, unacceptable for prospective applications (Metzger et al; IEEE Trans. Magn. 36, 30 (2000)). Furthermore, the current, and thus the deposition rate, decrease with time, eventually leading to cessation of the growth (a relevant decrease of cathodic current can be observed after only 0.5 s deposition) already at low thickness. Such processes thus lack flexibility and do not enable the fabrication of arrays of magnetic islands of the uniformity necessary in magnetic recording applications. Furthermore, extension of this type of process to other applications is hampered by the inhomogenity of the particles thus grown.

### SUMMARY OF THE INVENTION

Accordingly, one object of the present invention is to provide methods for the production of nanoscale particle arrays with high homogeneity and controllable in-plane or out-of-plane anisotropy.

Another object of this invention is to provide methods for the production of high density patterned magnetic recording media with greater flexibility and uniformity of the recording structure than conventional electrodeposition methods.

Another object of the invention is to provide nanometer scale particle arrays having high uniformity of particles and controllable in-plane or out-of-plane anisotropy.

These and other objects have been satisfied by the discovery of a method for the production of particle arrays, comprising:
growing one or more metals in a plurality of nanopores located in a surface of a substrate, wherein said growing step is achieved by reverse-pulse electrodeposition using a waveform pulse approximating a square or rectangular waveform,
the nanoscale particle arrays produced thereby, and the use of these nanoscale particle arrays in a variety of end applications, including but not limited to, magnetic recording as well as a variety of large scale particle arrays of metallic or non-metallic nanostructures for eletronic, optical and optoelectronic applications.

### BRIEF DESCRIPTION OF THE FIGURES

A more complete appreciation of the invention and many of the attendant advantages thereof will be readily obtained as the same becomes better understood by reference to the following detailed description when considered in connection with the accompanying drawings, wherein:

FIG. 1 depicts two examples of voltage waveforms and resulting current transients employed in the electrodeposition of Co arrays. (a) Sinusoidal AC waveform, (b) Asymmetric rectangular waveform.

FIG. 2 is an XRD diffractogram of a Co-filled alumite film grown by AC electrodeposition, using a sinusoidal waveform.

FIG. 3 shows in-plane and perpendicular squareness S=Mᵣ/Mₛ and coercivity vs. nanowire length l for Co arrays grown using a sinusoidal waveform.

FIG. 4 is a cross-sectional SEM image of a Co-filled alumite sample grown using a sinusoidal waveform.

FIG. 5 is a graphical representation of the electrodeposition rate when using the asymmetric rectangular waveform (pulse-reverse waveform) of FIG. 1b.

FIG. 6 is an SEM cross-section of alumite pores (no Co in the pores) after anodization in phosphoric acid—the pore widening to d=60 nm diameter is highlighted in the center.

FIG. 7 is a graphical representation of in-plane and out-of-plane coercivity H_{c} and squareness Mᵣ/Mₛ vs. average nanoparticle length l: a reorientational transition of the anisotropy is seen for l<20 nm.

FIG. 8(a) is a TEM cross-sectional view of Co arrays in alumite with average length 615 nm, grown by pulse-reverse electrodeposition. FIG. 8(b) Length distribution determined over 60 particles.

FIG. 9 is a TEM cross section of Co particles in ordered alumite, grown by pulse-reverse electrodeposition. Left: details of the microstructure. Right: overview, showing the thickness uniformity.

FIG. 10 are TEM selected-area diffraction patterns of (left) several grains of one Co particle, showing HCP ring patterns superposed to Al (112), and (right) the Co HCP (2423) diffraction pattern corresponding to one large grain.

FIG. 11 is a graphical representation of Coercivity and Squareness vs. particle length of short Co particle arrays.

FIG. 12 shows hysteresis loops of Co particle arrays with different thickness.

FIG. 13 shows ΔM curves vs. reduced applied field H/Hcr for various Co particle lengths.

FIG. 14 shows in-plane and out-of-plane hysteresis loops of l=100 nm Co nanoparticles, pore diameter d=25 nm, ratio c/a=4 using a sinusoidal waveform of FIG. 1a for electrodeposition.

FIG. 15 shows in-plane and out-of-plane hysteresis loops of short Co nanoparticles obtained with an asymmetric rectangular waveform (pulse-reverse waveform)—length l=5 nm, pore diameter d=60 nm, ratio c/a=1/12.

### DETAILED DESCRIPTION OF THE PREFERRED EMBODIMENTS

The present invention relates to a method for the production of nanometer scale particle arrays and the particle arrays produced thereby, as well as their use in a variety of applications, including but not limited to, the production of high density recording media.

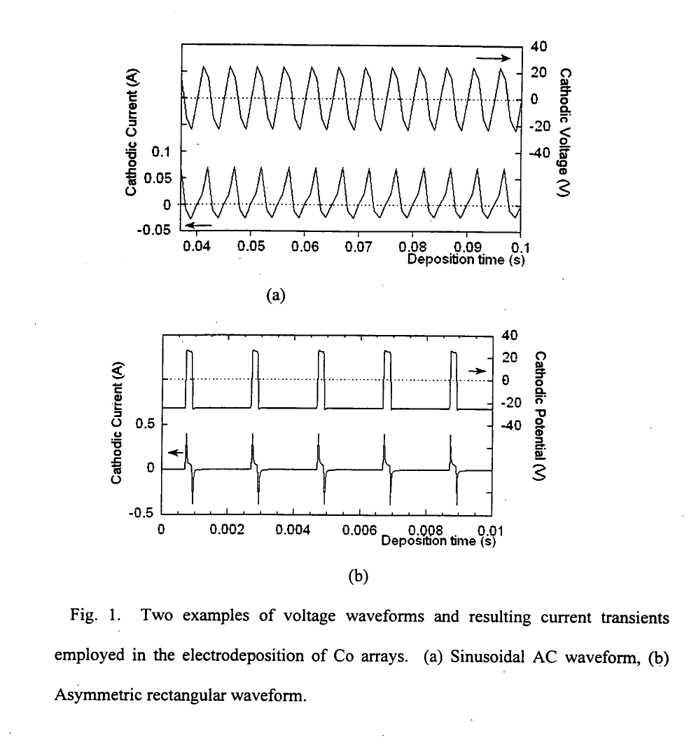

The method of the present invention comprises the pulse reverse electrodeposition of one or more metals in nanopores present in the surface of a substrate. In a preferred embodiment, the process comprises two main steps: the generation of an array of nanopores in a substrate, followed by pulse reverse electrodeposition of one or more metals, alloys or non-metals in the nanopores generated. Of particular importance in the method of the present invention is that the pulse reverse electrodeposition step uses a waveform herein referred to as “a rectangular waveform”. It is to be understood that the rectangular waveform of the present invention includes both square and rectangular waveforms, as well as waveforms that approximate square or rectangular waveforms. Examples of such waveforms that approximate square or rectangular waveforms include, but are not limited to, waveforms having a linear voltage or current increase to a plateau, holding at the plateau for a predetermined time, followed by a linear decrease of the voltage or current, waveforms that are sinusoidal, but which have a frequency (or cycle) that is sufficiently fast so as to provide nearly a linear increase at the beginning of the pulse and a nearly linear decrease after the plateau, wherein the linear increases and decreases of both types of pulse waveforms occur in 10⁻⁶ s or less, preferably in 10⁻⁷ seconds or less. The rectangular waveform is a waveform of either current or voltage pulses, alternately of opposite polarity, in order to effect the deposition. FIG. 1b shows an embodiment of the rectangular waveform pulses used in the present invention.

The timing of the waveform can take many alternatives, either symmetrical or asymmetrical in nature, as well as various shapes as noted above. In determining the particular timing of the rectangular waveform pulses, one of ordinary skill in the art can readily determine the optimum values of amplitude and duration of the cathodic portion of the pulse desired to maximize the nucleation rate and at the same time limit the growth of the metallic nuclei generated. Preferably, the anodic portion of the pulse is then used to discharge the capacitance of the double layer and thus interrupt deposition, and to allow sufficient time for the replenishment of metal ion concentration in the aluminum oxide channels. In general, the waveform can be designed, based on the knowledge of one of ordinary skill in the art, to adjust the requirements of the process under consideration. The pulses preferably have a duration ranging from 10⁻⁴ to 10⁻² S, more preferably from 1 millisecond to 10 milliseconds, most preferably about 2 milliseconds. Within this pulse, although the cathodic and anodic parts of the cycle can constitute any relative percentages, the cathodic part is preferably less than 20 percent of the cycle, and the anodic part is the rest (i.e. more than 80%) of the cycle. The amplitude of the pulse reverse electrodeposition pulses depends on the DC voltage used for anodization, which determines the thickness of the barrier layer of the oxide template in which the nanopores are arrayed (the lower the thickness of the barrier layer, the lower the minimum applicable voltage). For example, if a 40 V DC anodization step is used to generate the nanopores, then the AC electrodeposition potential would preferably range from 20 to 25 V (i.e. 40 to 50 V peak-to-peak). Preferably the peak-to-peak voltage ranges from 20 to 100 V, more preferably from 30 to 80V, most preferably from 30 to 60 V. Preferably the rise time of the rectangular waveform should be kept as low as possible to provide the best shaping of the waveform itself. More preferably, the rise time is maintained at a level of 10⁻⁷ s or lower. The pulse frequency preferably ranges from 1 to 10⁴ Hz, more preferably from 200 to 1000 Hz.

In a preferred embodiment using an anodized alumite as the nanopore array, the electrodeposition should be done immediately following anodization (i.e. on a freshly anodized alumite sample).

Conventional AC electrodeposition allows the production of magnetic particles with a wide range of aspect ratios, typically from 0.1:1 (for a disc-like particle) to 3:1 (for a stubby particle) to 1000:1 (for a long “nanowire”). However, the uniformity of particle length is very difficult to achieve for small or for large aspect ratios. Magnetic anisotropy is controlled by crystal anisotropy (when present, e.g. in Co), by shape effects and by the magnetic interactions among the magnetic islands. In some cases, the crystal anisotropy cannot be controlled due to polycrystalline growth or due to its low value in the material. The ability to control the uniformity of island thickness (height) using the present pulse reverse electrodeposition method enables one to control the easy direction of magnetization, by varying the aspect ratio of the particles. This effect can not be achieved using conventional AC electrodeposition, due to the large dispersion of island thickness. The present pulse reverse electrodeposition method allows the deposition of particles having aspect ratios in the range from 0.05:1 to 1000:1, and even higher if the nanopore has been made deep enough in its preparation.

The pulse-reverse electrodeposition method of the present invention is not limited to the fabrication of magnetic particles (a most preferred embodiment of the present invention), but can be applied to any metallic system that can be electrodeposited, including but not limited to, non-magnetic metals, semiconductors, and some oxides. Within the context of the present invention, the term “one or more metals” or “metals” in general includes not only the metallic elements singly, but also includes alloys as well as mixtures of metals. Most preferred as metals to be deposited by the present method (particularly for use in preparation of magnetic recording media) are the magnetic metals used in production of magnetic coatings in information storage media, particularly Fe, Co, Ni and their alloys. Other preferred metals, which could be used for optical and optoelectronic devices include, but are not limited to, Au, Ag and their alloys. These and other metals and alloys can be used to prepare the above noted media, as well as optical or optoelectronic devices of various nature for applications in digital communications technology.

The substrate for the present method can be any material in which it is possible to create nanopore arrays, preferably arrays that have high uniformity of the nanopore size and depth. The nanopore density is preferably from 10⁶ to 10¹² cm⁻², more preferably at least 10 Gigapores cm⁻². These arrays can be hexagonal or any other “perfectly” periodic order, preferably up to at least 1 square micrometer, more preferably up to at least 2 square micrometers, most preferably up to at least 4 square millimeters. The crystalline order in two dimensions can be measured by evaluating the short- and long-range order of these structures, based either on digitized electron microscopy images or atomic force microscopy images. An alternative method is the evaluation of the 2-dimensional Fourier transform of a digitized image of the substrate surface. The substrate can be made of a metal, alloy or a non-metal material. Most preferably the substrate is aluminum.

In a preferred embodiment, the pulse-reverse electrodeposition process is performed in anodic aluminum oxide to fabricate particle arrays with uniform and fixed aspect ratio for patterned magnetic media. The present method provides a distinct advantage over traditional plating methods in its ability to produce, in a controlled manner, both low and high aspect ratios, depending on the processing conditions, preferably aspect ratios in the range of from 0.05:1 to 1000:1. This range of aspect ratios allows for fabrication of new magnetic (or non-magnetic) structures useful in a number of sensing, storage or data processing applications. In magnetic recording media, the aspect ratio is preferably on the order of 0.1 to 5. Further, at aspect ratios below 0.1, it is possible that the film formed is non-continuous.

Nanostructures of various nature (metallic, semiconductive, etc.) for optical and information applications can be also fabricated in the same manner. Other advantages of the method are the low capital investment, and the possibility of processing non-planar structures.

The present method provides for the controlled and confined growth of metal particles in the pores of aluminum oxide. This further provides a unique means to synthesize nanometer sized functional devices, such as magnetic multi-layer with high values of giant magnetoresistance GMR (current-perpendicular-to-plane GMR), spin valve devices, etc (Dubois et al; Appl. Phys. Lett. 70, 396 (1987)), also of great interest as magnetic sensing and/or storage devices.

Transition metals plated into aluminum oxide pores have been proven to be good catalysts for the growth of multi-walled carbon nanotubes (CNT). The template provides for a very uniform and spatially ordered growth habit, yielding parallel nanotubes of similar length. The highly uniform electrodeposition of transition metal particles into the nanopores in alumite using the present method thus provides for unprecedented uniformity in the growth of nanotubes (e.g. CNT) in alumite, providing significant improvements in numerous applications in nanoelectronics, optics etc.

The present invention exploits the nanostructure of the template, in particular its regularity in pore size and location, and can control the thickness of the barrier layer using conventional techniques. The present invention provides the ability to fully control the nanostructure of the metal particles deposited in the nanopores of the array, preferably magnetic particles, and in particular, their crystalline orientation.

The pulse-reverse waveform method of the present invention was accomplished with the help of semi-quantitative estimates of the diffusion times necessary to deplete and replete the electrolyte near the deposition regions, thus allowing control of the growth process. However, other as yet unidentified phenomena are also involved, as the predictions on the basis of diffusion times alone are not very precise.

In the present method, due to the growth method and the periodic interruption of the growth, grain growth restarts at the beginning of each cathodic pulse, and the resulting grains in the initial stage of the growth process (up to 100 nm particle length) have their crystalline directions randomly oriented. As a consequence, the only way to obtain a definite magnetic anisotropy is through shape anisotropy. This can be done using the present invention by adjustment of the waveform together with an appropriate conditioning of the initial growth surface, the barrier layer. For example, the thickness of the barrier layer can be controlled by anodization with varying voltage; decreasing voltage while proceeding with the anodization decreases the thickness of the barrier layer, while also decreasing the thickness of the oxide walls. One preferred embodiment of such conditioning uses phosphoric acid under anodization conditions.

In the present invention, the preferred asymmetric rectangular waveform (an example of which is shown in FIG. 1b) is used to (a) allow sufficient time between successive cathodic pulses for the replenishment of the metal ions in the diffusion layer, and (b) enhance nucleation density and thus foster homogeneous growth. As an example, the results from deposition of Co⁺⁺ in alumite are shown in FIG. 5. The average length l of the nanowires formed increases linearly with time, indicating no gradual inhibition of the deposition process.

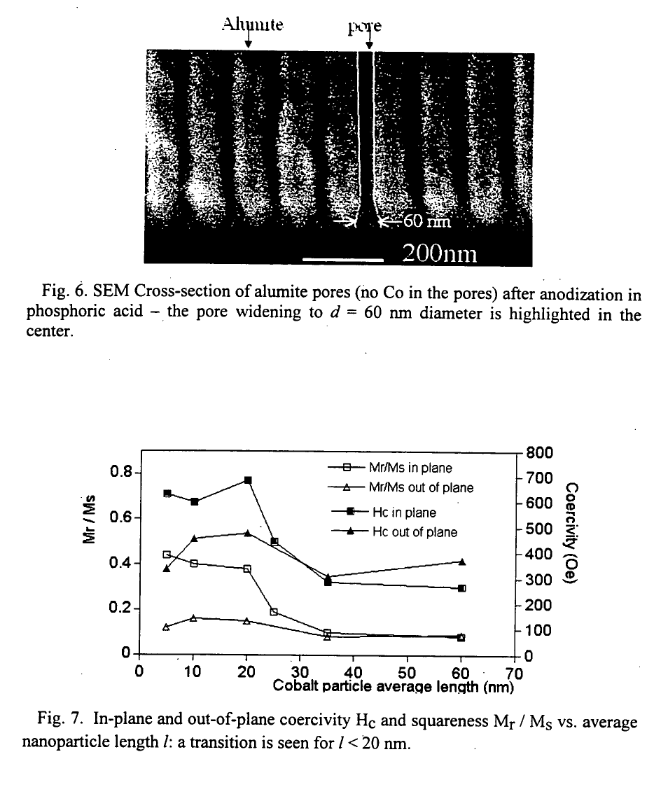

When performing the present process, the initial step is an anodization of the aluminum substrate to generate the nanopores in the surface. The barrier oxide layer, in particular its uniformity of thickness, on the aluminum surface can also be an important factor in obtaining controlled in-plane or out-of-plane magnetic anisotropy as preferred for the present invention. Thus, in a preferred embodiment the present process includes control of the uniformity of the thickness of the barrier oxide layer, preferably by further anodization to decrease the thickness and homogenize the layer. This provides a process of making magnetic nanoparticles with controlled anisotropy, in a large range of average nanoparticle length. By providing a uniform barrier layer thickness, it is believed that the process provides a more uniform energy barrier for island nucleation. The further anodization step to homogenize and decrease the thickness of the barrier layer can be performed under any anodization conditions suitable for aluminum, preferably under the same conditions as the initial anodization step, more preferably in 0.2 M H₃PO₄. FIG. 6 displays the effect of the successive anodization: the pore bottoms are widened and the barrier layer thickness decreases. As a consequence of pore widening, the nanowire diameter d and the surface fraction of magnetic material also increase. Using an asymmetric rectangular waveform, plus pore bottom conditioning enables a transition (FIG. 7) to an in-plane anisotropy below a 20 nm average nanowire length.

A further effect of the anodic pulse is the passivation of the existing nuclei, so that, at each cathodic pulse growth can start again, thus increasing the uniformity of the structure. One minor drawback of this deposition method is its low efficiency. Direct measurements (cathodic efficiency=charge used for metal reduction/total charge passed) yield 2 to 5% efficiency, while estimation of the cathodic current in one period confirms that not all the current is used up by the reduction of Co⁺⁺ ions. The main side reactions are hydrogen evolution, that at pH 3.8 takes place mainly by water splitting: 2H₂O+2e⁻→2OH⁻+H₂, and Al oxide-hydroxide dissolution: AlOOH+e⁻→AlO₂⁻+½ H₂. The latter reaction is probably responsible for the damage observed on oxide templates after prolonged deposition.

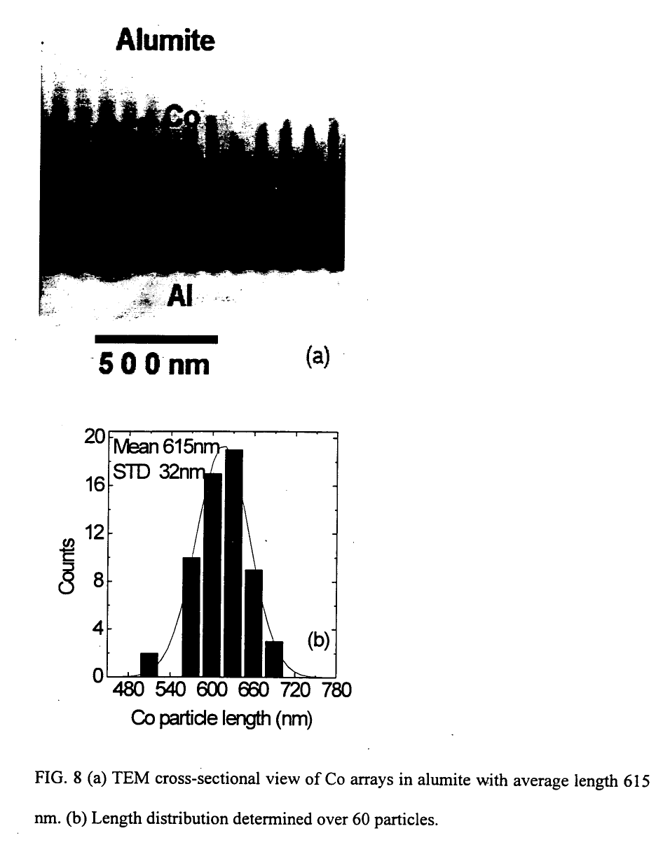

In the present process, no decrease in deposition current with time is observed, so that high aspect ratio structures can be grown simply by linearly increasing the duration of the ECD (electrochemical deposition) process. Using the present process, nanoparticle arrays of up to 1000 nm length were grown. However, the length of the nanoparticle arrays is only limited by the length of the nanopore oxide channels, which can be formed up to 100 microns or even longer if desired. Magnetic structures of high uniformity are obtained; for example, on Co arrays with an average length <L>=615 nm (FIG. 8a) a standard deviation σ=32 nm, corresponding to

$$\frac{σ}{< L >} = 5 \% ,$$

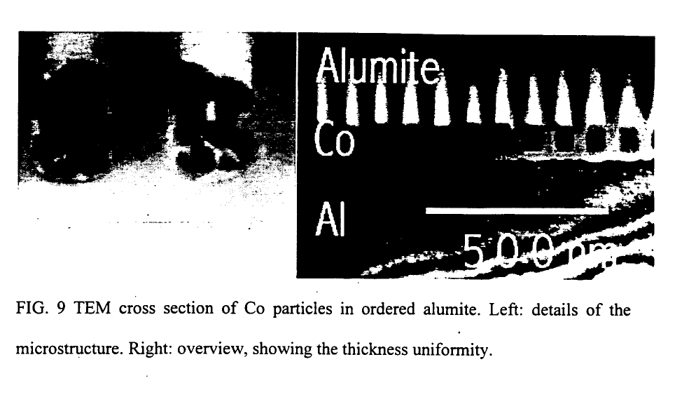

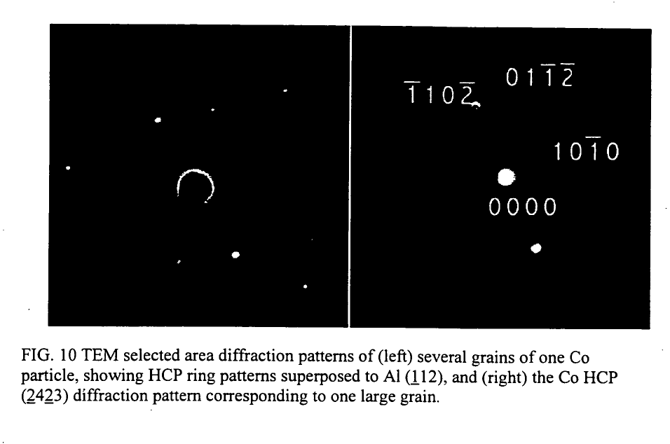

is observed (FIG. 8b). Some uncertainty in the estimate of particle length by TEM is due to the varying contrast inside single Co particles. As directly evidenced by TEM cross sections of Co nano-structures (FIG. 9), low aspect ratio arrays grow also in a very uniform manner. Growth of the particles takes place by periodic nucleation and interrupted growth, which leads to a polycrystalline structure. TEM selected-area micro diffraction patterns on several grains at a time (FIG. 10, left) and on single grains (FIG. 10, right) show HCP crystallites with random relative orientation.

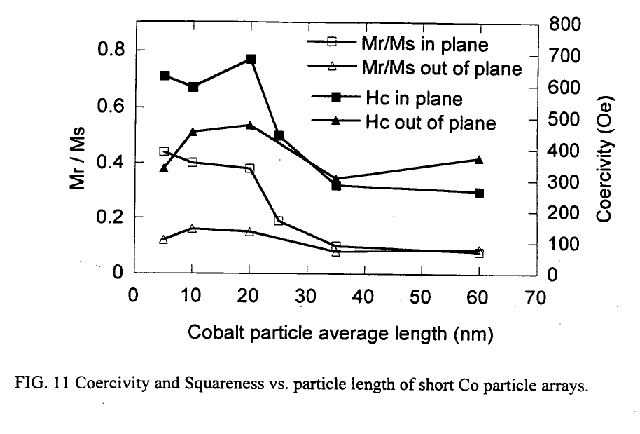

Coercivity of arrays with thickness in the 5-220 nm range varies between 250 and 700 Oe (FIG. 11), lower than the values expected for coherent switching processes. The Co nanoparticles have a diameter (60 nm) larger than the single-domain critical radius (≦37 nm). Therefore, inhomogeneous switching processes are expected, in qualitative agreement with the coercivity observed.

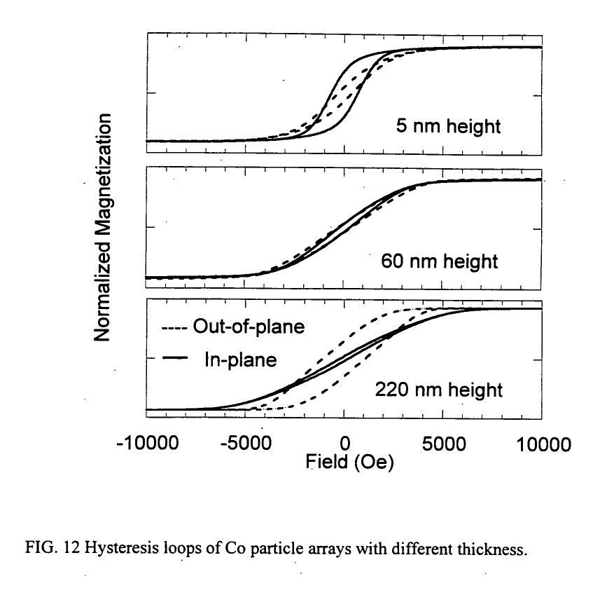

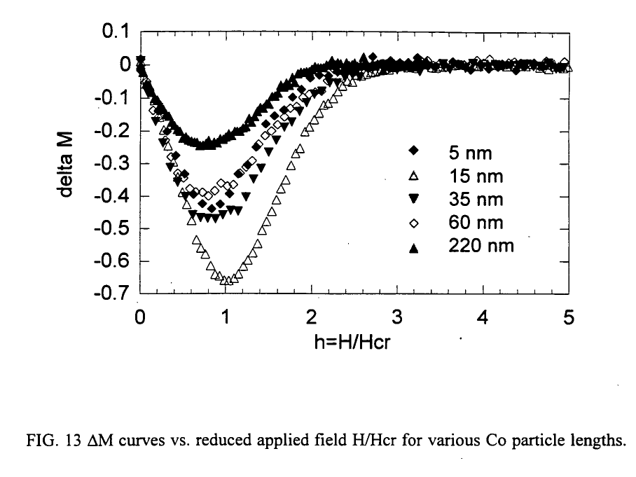

A clear reorientation of the array anisotropy from perpendicular to in-plane with decreasing thickness—in the former art concealed by the wide particle length distribution—is also observed in arrays of the present invention (FIGS. 10 and 11). The aspect ratio a (height/radius) at which this transition takes place is around two, in fair agreement with the theoretical reorientational transition for ordered arrays of magnetostatically coupled particles with no magnetocrystalline anisotropy. Thus, as already suggested by the polycrystallinity and random orientation of the nanoparticles, shape effects and interparticle interactions dominate the magnetic behavior of the nanoparticle arrrays prepared by the method of the present invention. As a consequence, the transition, from in-plane to perpendicular anisotropy, can be controlled by varying the particle aspect ratio and, to a minor extent, the packing density. The importance of interparticle interactions is confirmed by the skew of the hysteresis loops in FIG. 12, and further confirmed by ΔM measurements in the array plane. ΔM curves are always negative, with normalized minima in the range 0.25 to 0.7 (FIG. 13), evidencing the predominance of magnetostatic interactions. Interactions are strongest at an intermediate thickness of 15 nm, indicating that inhomogeneous magnetization configurations with lower demagnetizing fields become more stable in the switching process of particles with larger thickness.

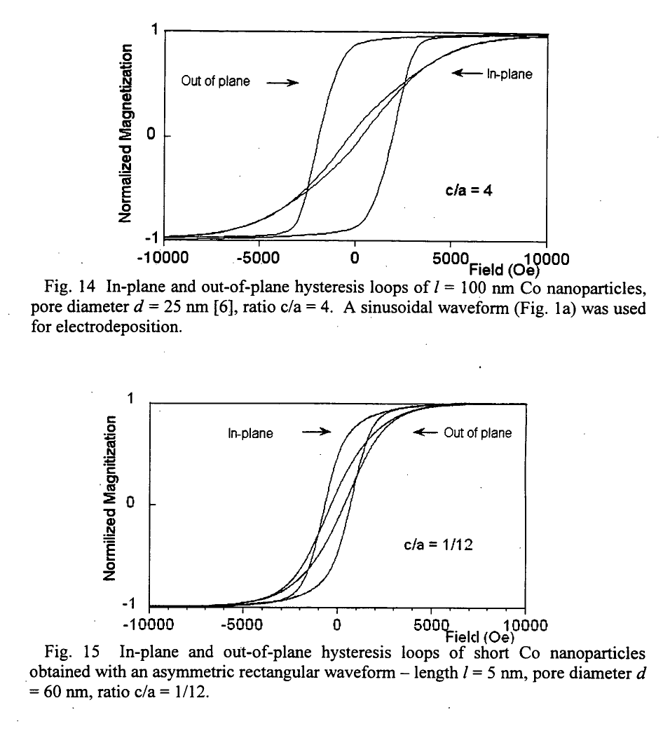

Typical hysteresis loops of nanowires generated by the present process (shown for a preferred embodiment of Co as the metal), produced using the waveforms in FIGS. 1a and 1b*, are shown in FIGS. 13 and 14, for the use of sinusoidal waveform and the asymmetric rectangular waveform of the present invention, respectively. The conventional sinusoidal wave electrodeposition process yields high out-of-plane squareness and perpendicular coercivity of 2 kOe (FIG. 14). The asymmetric rectangular wave, plus pore bottom conditioning of the present invention, yields instead an in-plane squareness up to 0.45 and coercivity of 700 Oe (FIG. 15). The in-plane squareness, produced by the present process, tends to be lower than expected for a random 2-D non-interacting array of Stoner-Wohlfarth particles (0.64). This deviation is believed to be attributable to the demagnetizing interactions among the Co nanowires, and to a minor extent to crystallographic effects.

In practice the present method provides the deposition of metals in nanopores to provide in-plane squareness of from 0 to 0.6, preferably up to 0.51, and in-plane coercivity of 1180 Oe (for short particles) and perpendicular coercivity of up to 2 kOe (for long particles). With the appropriate choice of materials (for instance, using CoNi or CoPt alloys), coercivity can be increased up to 3000 Oe. With use of other materials (Fe or Ni) coercivity can be decreased to much less than 100 Oe. These latter values are of little interest in magnetic recording, but can be of interest in the production of magnetic sensors based on nanoscale particle arrays. The preferred value of squareness depends on the application for which the nanoparticle array will be used. For example, for a magnetic recording medium for in-plane recording, a squareness of 1 in the plane and 0 out of plane is preferred. The inverse would be true for a recording medium for perpendicular recording. These border conditions are achievable only if the particles are far away from each other, which is not practical when a high recording density is desired. A preferred range of squareness is from 0 to 0.6, with from 0 to 0.51 being more preferred.

The resulting particle arrays can be used in a variety of applications and devices, as described above. Of particular preference is the use in high-density magnetic information storage media. The magnetic storage media produced using the present invention particle arrays can have recording densities of at least 40 Gb/in², preferably at least 100 Gb/in², most preferably on the order of 10³ Gb/in². The recording density is only limited by the achievable pore density. Ideally, using a pore density of the optimum density (about 5 nm pores in a 20-30 nm cell size), the recording density could reach about 1/(cell diameter)².

Due to the pulse-reverse ECD process employed for particle growth, the nanoparticles generated are polycrystalline and the grains are randomly oriented. The magnetic properties of the array are mainly determined by particle shape and interparticle interactions, and the reorientational transition of the anisotropy can be easily controlled by varying the aspect ratio. Utilizing reported stability criteria, nanoparticle arrays prepared by the present invention method, particularly those with bit density of at least 64 Gb/in², exhibit good thermal stability. The pulse-reverse ECD method of the present invention thus presents a great potential for the synthesis of highly uniform nano-structures of various nature.

Having generally described this invention, a further understanding can be obtained by reference to certain specific examples which are provided herein for purposes of illustration only and are not intended to be limiting unless otherwise specified.

### EXAMPLES

Anodization—A pure Al sheet (99.998%) was degreased in 5% NaOH solution at 60° C., then rinsed by de-ionized water. In order to smoothen the Al surface, the Al sheet was first electropolished in perchloric acid-ethanol electrolyte, and successively cleaned with warm de-ionized water and air-dried. Masuda's process (as described in Masuda et al, Science, 268, pp. 1466-1468 (1995)) was employed to synthesize highly ordered Al-oxide porous films. The Al sample was first anodized (0.3 M oxalic acid, 40 V DC, 15° C.) for 24 hours, then the oxide film was dissolved away in a mixed solution of 0.2 M H₂CrO₄ and 0.4 M H₃PO₄ at 60° C. Finally, one side of the Al sheet surface was anodized again for 0.5-3 hours. Perfectly ordered, hexagonal pore arrays up to 10 μm scale can be achieved by this method. The pore diameter was 25 nm; the pore-to-pore distance was 110 nm.

Electrodeposition—Cobalt nanowires were grown under voltage control, from an aqueous bath containing 0.1 M CoSO₄ and 0.5 M H₃BO₃. A graphite sheet (thickness: 0.5 mm) was used as counter-electrode. The cell voltage was applied through a Kepco bipolar power amplifier, computer-controlled with Labview® software (National Instruments). The software allowed the generation of various voltage waveforms, as well as the recording of the cell voltage and current vs. time. A scanning electron microscope (SEM) was used to observe the morphologies of the alumite and the metal nanowires. The cobalt particles inside the alumite were detected by Energy Dispersive X-ray analysis (EDAX). Magnetic properties were measured by an Alternating Gradient Magnetometer (AGM). The crystalline orientation of cobalt nanowires with high aspect ratio c/a was determined by X-ray diffraction (XRD).

Sinusoidal and square voltage waveforms of various frequencies f were used to grow Co islands. In the range f=200 to 1,000 Hz, magnetic properties were independent of f. FIG. 1 displays representative voltage waveforms and the corresponding current transients. Positive current values correspond to cathodic processes, which include Co deposition.

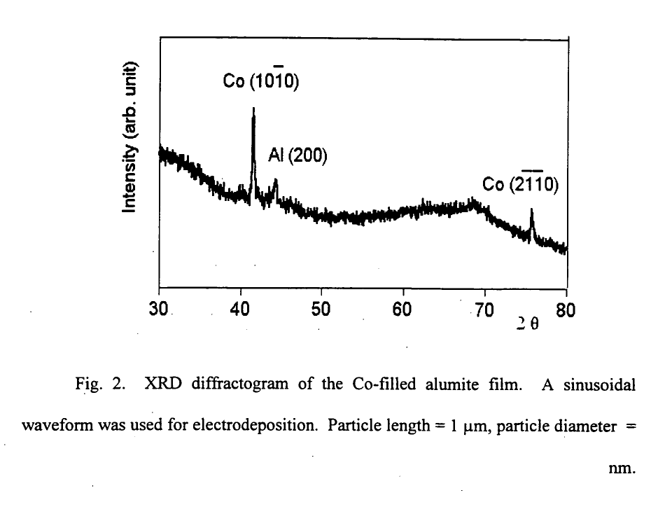

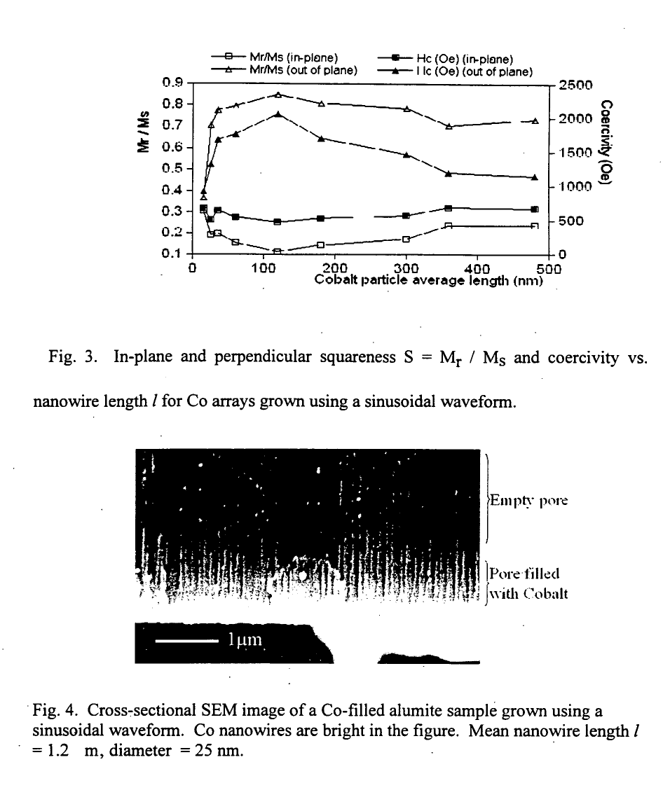

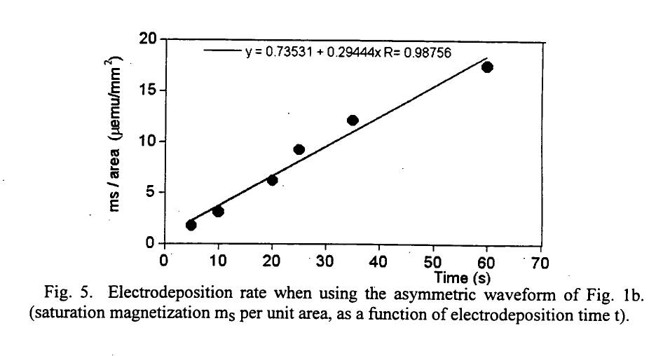

Cobalt nanowires grown by using sinusoidal voltage waveforms exhibit an HCP structure with (1010) preferred orientation (FIG. 2), i.e. the c-axis in the film plane. Magnetic properties as a function of the average nanowire length l (calculated from the magnetic moment and the alumite geometry ) are shown in FIG. 3. No transition from perpendicular to in plane anisotropy was observed with decreasing length, as would be expected on the basis of shape and crystallographic effects. This is because the Co nanowires grow non-uniform in length (FIG. 4), preventing the observation of an average in-plane anisotropy. Thus the use of sinusoidal waveforms does not allow the synthesis of patterned media with longitudinal anisotropy and would not allow the reliable storage of information due to the inhomogeneity of the magnetic properties of single particles. A further shortcoming of this technique was the exponential decrease with time of the average current, and thus of the deposition rate, probably due to the gradual depletion of the Co⁺⁺ ions concentration in the diffusion layer near the substrate.

The asymmetric rectangular waveform of FIG. 1b was used to (a) allow sufficient time between successive cathodic pulses for the replenishment of Co⁺⁺ ions in the diffusion layer, and (b) enhance nucleation density, and thus foster homogeneous growth. The results are shown in FIG. 5: the average length l of the Co nanowires increased linearly with time, indicating no gradual inhibition of the deposition process. As with the sinusoidal waveform, however, no transition to an in-plane anisotropy with decreasing average length was observed, and the morphology of the Co columns was similar to that shown in FIG. 4. This behavior is attributed to the non-uniform thickness of the barrier oxide layer present at the bottom of the pores, which constitutes a non-uniform energy barrier for island nucleation. The second anodization step noted above was performed in 0.2 M H₃PO₄; it was utilized to homogenize and decrease the thickness of the barrier layer. FIG. 6 displays the effect of this second anodization: the pore bottoms were widened to d=60 nm and the barrier layer thickness decreased. As a consequence of pore widening, the nanowire diameter d and the surface fraction of magnetic material also increased. Using an asymmetric rectangular waveform, plus pore bottom conditioning, enabled a transition (FIG. 7) to an in-plane anisotropy below a 20 nm average nanowire length. A rectangular waveform was used in this example of the present invention, and pulse-reverse ECD under voltage control was performed, with the rectangular waveform having a square cathodic pulse (−25 V for 2×10⁻⁴ s) and a prolonged anodic one (+25 V for 18×10⁻⁴ s).

Conventional ECD using AC sinusoidal waveforms yields magnetic particles with a wide size distribution (Metzger et al., IEEE Trans. Magn., 36, p. 30 (2000)). For example, Co particles with an average length <L>=1203 nm exhibit a standard deviation σ=197 nm, giving

$$\frac{σ}{< L >} = 16 \%$$

(M. Sun et al., Appl. Phys. Lett., accepted and in press). In addition, the ECD current decreases with time, eventually leading to cessation of the growth.

Demagnetizing fields were calculated in the dipole approximation, and the corresponding corrections were performed on the hysteresis loops. These corrections increasingly overestimated the actual demagnetizing fields, the higher the thickness of the arrays, indicating that, indeed, the actual demagnetizing fields decrease in intensity for thicker arrays.

Magnetic viscosity measurements were carried out with the array plane oriented parallel to the applied field. The array was first saturated with an 18 kOe field, then a reverse field Hᵣₑᵥ=0.1 to 10 times of the remanent coercivity H_{cr} was applied for different durations t=6 to 600 s, and successively shut down to measure the remanence Mᵣ(t). A plot of Mᵣ(t)/Mₛ vs. ln(t) at different Hᵣₑᵥ was utilized, to derive the remanent viscosity δᵣ as −dMr/dln(t). The time-dependent remanent coercivity H_{cr}(t) was determined, by plotting Mᵣ(Hᵣₑᵥ), using t as a parameter; the intersections of such lines with Mᵣ=0 were taken to be H_{cr}(t). These values were fitted to a Sharrock's law. From the above analysis, values of δᵣ<2, and a stability ratio C⁻¹=KᵤV/kT between 100 and 550 were determined. Utilizing the criterion for thermal stability C⁻¹>64, these arrays are thermally stable. Assuming a storage configuration of one island per bit, the recording density possible with these arrays was found to be approximately 64 Gbit/in², demonstrating that the thermal stability limit can indeed be pushed back by media patterning.

Obviously, additional modifications and variations of the present invention are possible in light of the above teachings. It is therefore to be understood that within the scope of the appended claims, the invention may be practiced otherwise than as specifically described herein.

1. A method for the production of a nanoscale particle array, comprising:
growing one or more metals or non-metals in a plurality of nanopores located in a surface of a substrate, wherein said growing is performed by reverse-pulse electrodeposition using a rectangular waveform pulse.

2. The method of claim 1, wherein said rectangular waveform pulse has a peak-to-peak amplitude of 20 to 100 V for a cathodic portion of the pulse and a peak-to-peak amplitude of 20 to 100 V for an anodic portion of the pulse.

3. The method of claim 2, wherein said rectangular waveform pulse has an overall duration of 10⁻⁴ to 10⁻² s.

4. The method of claim 3, wherein said rectangular waveform pulse has a frequency of 1 to 10⁴ Hz.

5. The method of claim 1, wherein said rectangular waveform pulse is a symmetrical pulse.

6. The method of claim 1, wherein said rectangular waveform pulse is an asymmetrical pulse.

7. The method of claim 1, wherein said one or more metals are selected from the group consisting of magnetic metals, non-magnetic metals, semiconductors and metal oxides.

8. The method of claim 7, wherein said one or more metals are selected from the group consisting of magnetic metals and alloys thereof.

9. The method of claim 8, wherein said magnetic metals are selected from the group consisting of Fe, Co, Ni and alloys thereof.

10. The method of claim 1, wherein said substrate is aluminum.

11. The method of claim 1, wherein said plurality of nanopores are present in said substrate at a density of from 10⁶ to 10¹² cm⁻².

12. A method for producing nanoscale particle arrays, comprising:
forming a plurality of nanopores in a surface of a substrate; and
growing one or more metals or non-metals in said plurality of nanopores, wherein said growing is performed by reverse-pulse electrodeposition using a rectangular waveform pulse.

13. The method of claim 12, wherein said rectangular waveform pulse has a peak-to-peak amplitude of 20 to 100 V for a cathodic portion of the pulse and a peak-to-peak amplitude of 20 to 100 V for an anodic portion of the pulse.

14. The method of claim 13, wherein said rectangular waveform pulse has an overall duration of 10⁻⁴ to 10⁻² s.

15. The method of claim 14, wherein said rectangular waveform pulse has a frequency of 1 to 10⁴ Hz.

16. The method of claim 12, wherein said rectangular waveform pulse is a symmetrical pulse.

17. The method of claim 12, wherein said rectangular waveform pulse is an asymmetrical pulse.

18. The method of claim 12, wherein said one or more metals are selected from the group consisting of magnetic metals, non-magnetic metals, semiconductors and metal oxides.

19. The method of claim 18, wherein said one or more metals are selected from the group consisting of magnetic metals and alloys thereof.

20. The method of claim 19, wherein said magnetic metals are selected from the group consisting of Fe, Co, Ni and alloys thereof.

21. The method of claim 12, wherein said substrate is aluminum.

22. The method of claim 12, wherein said plurality of nanopores are present in said substrate at a density of from 10⁶ to 10¹² cm⁻².

23. The method of claim 12, wherein said forming step is performed by anodization of the surface of the substrate.

24. The method of claim 23, wherein said anodization is performed in a solution comprising oxalic acid, and said substrate is aluminum.

25. A method for production of a nanoscale particle array, comprising:
a step of growing one or more metals or non-metals in a plurality of nanopores formed in a surface of a substrate.

26. The method of claim 25, wherein said step of growing is preceded by a step of forming said plurality of nanopores in the surface of the substrate.

27-39. (canceled)
